(19) United States
(12) Patent Application Publication
(10) Pub. No.: US 2026/0047454 A1
(43) Pub. Date: Feb. 12, 2026

(54) FAN-OUT SEMICONDUCTOR PACKAGE

(71) Applicant: SK hynix Inc., Icheon-si Gyeonggi-do (KR)

(72) Inventor: Kyoung Tae EUN, Icheon-si Gyeonggi-do (KR)

(73) Assignee: SK hynix Inc., Icheon-si Gyeonggi-do (KR)

(21) Appl. No.: 19/014,893

(22) Filed: Jan. 9, 2025

(30) Foreign Application Priority Data
Aug. 6, 2024 (KR) 10-2024-0104350

(51) Int. Cl. H01L 23/00; H01L 23/31; H01L 23/538; H01L 25/065; H10B 80/00; H10D 80/30

(52) U.S. Cl. CPC H01L 24/20; H01L 23/3135; H01L 23/5386; H01L 23/5389; H01L 24/24; H01L 25/0657; H01L 23/3128; H01L 24/05; H01L 24/06; H01L 24/19; H01L 24/32; H01L 24/73; H01L 2224/05541; H01L 2224/06135; H01L 2224/19; H01L 2224/2101; H01L 2224/214; H01L 2224/215; H01L 2224/24155; H01L 2224/32145; H01L 2224/32225; H01L 2224/73267; H01L 2225/06562; H01L 2924/1815; H10B 80/00; H10D 80/30

(57) ABSTRACT

A fan-out semiconductor package includes a semiconductor chip; a metal pillar disposed on the semiconductor chip; a bonding metal layer disposed on the metal pillar; a bonding wire disposed on the bonding metal layer; a sealing layer over the semiconductor chip, and surrounding the metal pillar, the bonding metal layer, and the bonding wire; and a redistribution layer disposed on the sealing layer and the bonding wire.

### CROSS-REFERENCE TO RELATED APPLICATION

The present application claims priority under 35 U.S.C. § 119(a) to Korean Patent Application No. 10-2024-0104350 filed in the Korean Intellectual Property Office on Aug. 6, 2024, which application is incorporated herein by reference in its entirety.

### BACKGROUND

### 1. Technical Field

The present disclosure generally relates to semiconductor packages, including but not limited to a fan-out semiconductor package.

### 2. Related Art

A vertical fan-out semiconductor package uses wires that extend vertically. Because a semiconductor chip and redistribution line patterns are connected by vertical wires in a vertical fan-out semiconductor package, the vertical fan-out semiconductor package may advantageously be made thinner than conventional packages.

### SUMMARY

In an embodiment, a fan-out semiconductor package may include: a semiconductor chip; a metal pillar disposed on the semiconductor chip; a bonding metal layer disposed on the metal pillar; a bonding wire disposed on the bonding metal layer; a sealing layer over the semiconductor chip and surrounding the metal pillar, the bonding metal layer, and the bonding wire; and a redistribution layer disposed on the sealing layer and the bonding wire.

In an embodiment, a fan-out semiconductor package may include: a first semiconductor chip; a first metal pillar disposed on the first semiconductor chip; a bonding metal layer disposed on the first metal pillar; a second semiconductor chip stacked on the first semiconductor chip and offset from the first semiconductor chip by a first distance in a first direction; a second metal pillar disposed on the second semiconductor chip; a bonding wire disposed on the bonding metal layer; a sealing layer over the first semiconductor chip, the second semiconductor chip, and surrounding the first metal pillar, the second metal pillar, the bonding metal layer, and the bonding wire; and a redistribution layer disposed on the sealing layer, the bonding wire, and the second metal pillar.

In an embodiment, a fan-out semiconductor package may include: a first semiconductor chip; a first metal pillar disposed on the first semiconductor chip; a first bonding metal layer disposed on the first metal pillar; a second semiconductor chip stacked on the first semiconductor chip by a first offset in the first direction; a second metal pillar disposed on the second semiconductor chip; a second bonding metal layer disposed on the second metal pillar; a third semiconductor chip stacked on the second semiconductor chip by a second offset in a direction opposite to the first direction; a third metal pillar disposed on the third semiconductor chip; a first bonding wire disposed on the first bonding metal layer; a second bonding wire disposed on the second bonding metal layer; a sealing layer over the first semiconductor chip, the second semiconductor chip, the third semiconductor chip and surrounding the first metal pillar, the second metal pillar, the third metal pillar, the first bonding metal layer, the second bonding metal layer, the first bonding wire, and the second bonding wire; and a redistribution layer disposed on the sealing layer, the first bonding wire, the second bonding wire, and the third metal pillar.

In an embodiment, a semiconductor package may include a metal pillar disposed on a semiconductor chip; a bonding wire disposed between the metal pillar and a redistribution layer; and a sealing layer over the semiconductor chip and surrounding the metal pillar and the wire, wherein the redistribution layer is disposed on the first sealing layer and the wire.

### BRIEF DESCRIPTION OF THE DRAWINGS

FIG. 1 is a cross-sectional view of a fan-out semiconductor package according to an embodiment of the present disclosure.

FIG. 2 is a plan view of a first semiconductor chip of FIG. 1.

FIG. 3 is a plan view illustrating a first chip pad, a first metal pillar, and a first bonding wire FIG. 1.

FIG. 4 is a cross-sectional view taken along a line A-A′ of FIG. 3 according to an embodiment of the present disclosure.

FIG. 5 is a cross-sectional view illustrating a first chip pad, a first metal pillar, and a first bonding wire according to an embodiment of the present disclosure.

FIG. 6 to FIG. 8 are cross-sectional views illustrating a fan-out semiconductor package formed using a method of manufacturing a fan-out semiconductor package according to an embodiment of the present disclosure.

FIG. 9 is a diagram of a capillary of a wire bonding device.

FIG. 10 is a graph showing change in the maximum height of a bonding wire versus change in the pitch of a chip pad.

### DETAILED DESCRIPTION

Embodiments of the present disclosure are described detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” or “under,” another element, the elements may directly contact each other or an intervening element may be disposed between the elements.

Terms such as “vertical,” “horizontal,” “under,” “over,” “on,” “side,” “upper,” “lower,” “left,” “right,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

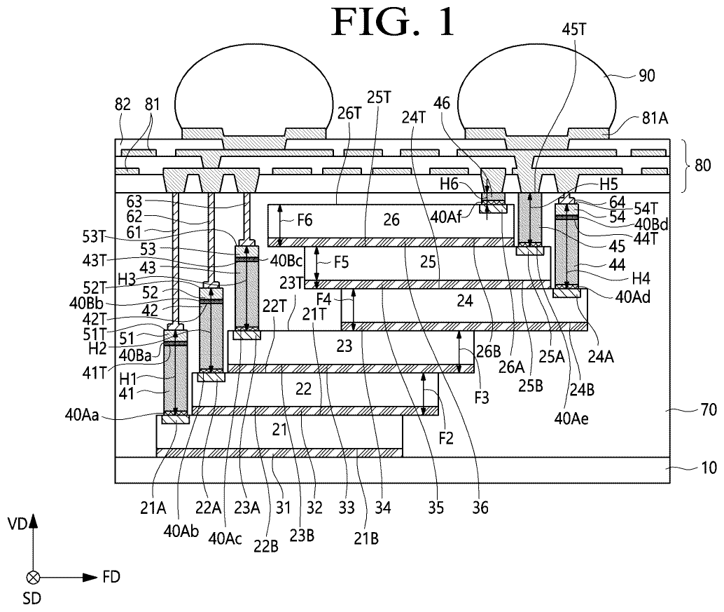

FIG. 1 is a cross-sectional view of a fan-out semiconductor package according to an embodiment of the present disclosure.

Referring to FIG. 1, the fan-out semiconductor package according to an embodiment of the present disclosure includes a first sealing layer 10, semiconductor chips 21 to 26, metal pillars 41 to 46, bonding metal layers 51 to 54, bonding wires 61 to 64, a second sealing layer 70, and a redistribution layer 80.

The first sealing layer 10 includes an insulating layer. The insulating layer may include an epoxy molding compound (EMC). The epoxy molding compound may include resin and various types of filler dispersed in the resin. The first sealing layer 10 may include an epoxy molding compound film (EMC film) obtained by processing an epoxy molding compound (EMC) into a film form.

The semiconductor chips 21 to 26 are stacked on the first sealing layer 10. Although the drawings include six semiconductor chips, the present disclosure is not limited to this example. The quantity of semiconductor chips may vary.

Each of the semiconductor chips 21 to 26 may include nonvolatile memory such as NAND, NOR, PRAM (phase change random access memory), and MRAM (magnetoresistive random access memory), volatile memory such as DRAM (dynamic random access memory) and SRAM (static random access memory), a processor such as a logic circuit, and so forth.

The first semiconductor chip 21 has an upper surface 21T on which a first chip pad 21A is disposed and a lower surface 21B opposite to the upper surface 21T. The first chip pad 21A is electrically connected to an integrated circuit inside the first semiconductor chip 21. The first chip pad 21A is disposed near one edge of the upper surface 21T of the first semiconductor chip 21 in a first direction FD, for example, a left edge as shown in FIG. 1.

The first metal pillar 41 is disposed on the first chip pad 21A, and the first bonding metal layer 51 is disposed on the first metal pillar 41. A first adhesive layer 31 is disposed on the lower surface 21B of the first semiconductor chip 21. The first adhesive layer 31 attaches the lower surface 21B of the first semiconductor chip 21 to the first sealing layer 10.

The second semiconductor chip 22 has an upper surface 22T on which a second chip pad 22A is disposed and a lower surface 22B opposite to the upper surface 22T. The second chip pad 22A is electrically connected to an integrated circuit inside the second semiconductor chip 22. The second chip pad 22A is disposed near one edge of the upper surface 22T of the second semiconductor chip 22 in the first direction FD, for example, a left edge as shown in FIG. 1.

The second metal pillar 42 is disposed on the second chip pad 22A, and the second bonding metal layer 52 is disposed on the second metal pillar 42. The second semiconductor chip 22 is stacked on the first semiconductor chip 21 by a first offset in the first direction FD such that the first metal pillar 41 and the first bonding metal layer 51 are not covered by the second semiconductor chip 22. The second semiconductor chip 22 is disposed beside or spaced apart from the first metal pillar 41 in the first direction FD and partially over the first semiconductor chip 21 in the vertical direction VD. The first metal pillar 41 extends substantially vertically near the side of the second semiconductor chip 22.

A second adhesive layer 32 is disposed on the lower surface 22B of the second semiconductor chip 22. The second adhesive layer 32 attaches the lower surface 22B of the second semiconductor chip 22 to the upper surface 21T of the first semiconductor chip 21.

The third semiconductor chip 23 has an upper surface 23T on which a third chip pad 23A is disposed and a lower surface 23B opposite to the upper surface 23T. The third chip pad 23A is electrically connected to an integrated circuit inside the third semiconductor chip 23. The third chip pad 23A is disposed near one edge of the upper surface 23T of the third semiconductor chip 23 in the first direction FD, for example, a left edge as shown in FIG. 1.

The third metal pillar 43 is disposed on the third chip pad 23A, and the third bonding metal layer 53 is disposed on the third metal pillar 43. The third semiconductor chip 23 is stacked on the second semiconductor chip 22 by a second offset in the first direction FD such that the second metal pillar 42 and the second bonding metal layer 52 are not covered by the third semiconductor chip 23. The third semiconductor chip 23 is offset with respect to the second semiconductor chip 22 in the same direction as the second semiconductor chip 22 is offset with respect to the first semiconductor chip 21. The third semiconductor chip 23 is disposed beside or spaced apart from the second metal pillar 42 in the first direction FD and partially over the second semiconductor chip 22 in the vertical direction VD. The second metal pillar 42 extends substantially vertically near the side of the third semiconductor chip 23.

A third adhesive layer 33 is disposed on the lower surface 23B of the third semiconductor chip 23. The third adhesive layer 33 attaches the lower surface 23B of the third semiconductor chip 23 to the upper surface 22T of the second semiconductor chip 22.

The fourth semiconductor chip 24 has an upper surface 24T on which a fourth chip pad 24A is disposed and a lower surface 24B opposite to the upper surface 24T. The fourth chip pad 24A is electrically connected to an integrated circuit inside the fourth semiconductor chip 24. The fourth chip pad 24A is disposed near one edge of the upper surface 24T of the fourth semiconductor chip 24 in the first direction FD, for example, a right edge as shown in FIG. 1.

The fourth metal pillar 44 is disposed on the fourth chip pad 24A, and the fourth bonding metal layer 54 is disposed on the fourth metal pillar 44. The fourth semiconductor chip 24 is stacked on the third semiconductor chip 23 by a third offset in the first direction FD such that the third metal pillar 43 and the third bonding metal layer 53 are not covered by the fourth semiconductor chip 24. The fourth semiconductor chip 24 is offset with respect to the third semiconductor chip 23 in the same direction as the third semiconductor chip 23 is offset with respect to the second semiconductor chip 22.

The fourth semiconductor chip 24 is disposed beside or spaced apart from the third metal pillar 43 in the first direction FD and partially over the third semiconductor chip 23 in the vertical direction VD. The third metal pillar 43 extends substantially vertically near the side of the fourth semiconductor chip 24.

A fourth adhesive layer 34 is disposed on the lower surface 24B of the fourth semiconductor chip 24. The fourth adhesive layer 34 attaches the lower surface 24B of the fourth semiconductor chip 24 to the upper surface 23T of the third semiconductor chip 23.

The fifth semiconductor chip 25 has an upper surface 25T on which a fifth chip pad 25A is disposed and a lower surface 25B opposite to the upper surface 25T. The fifth chip pad 25A is electrically connected to an integrated circuit inside the fifth semiconductor chip 25. The fifth chip pad 25A is disposed near one edge of the upper surface 25T of the fifth semiconductor chip 25 in the first direction FD, for example, a right edge as shown in FIG. 1. The fifth metal pillar 45 is disposed on the fifth chip pad 25A.

The fifth semiconductor chip 25 is stacked or disposed on the fourth semiconductor chip 24 by a fourth offset such that the fourth metal pillar 44 and the fourth bonding metal layer 54 are not covered by the fifth semiconductor chip 25. The fifth semiconductor chip 25 is offset with respect to the fourth semiconductor chip 24 in a direction opposite to the direction that the fourth semiconductor chip 24 is offset with respect to the third semiconductor chip 23. The fifth semiconductor chip 25 is disposed between the third metal pillar 43 and the fourth metal pillar 44 and partially over the fourth semiconductor chip 24 in the vertical direction VD. The fourth metal pillar 44 extends substantially vertically near the side of the fifth semiconductor chip 25.

A fifth adhesive layer 35 is disposed on the lower surface 25B of the fifth semiconductor chip 25. The fifth adhesive layer 35 attaches the lower surface 25B of the fifth semiconductor chip 25 to the upper surface 24T of the fourth semiconductor chip 24.

The sixth semiconductor chip 26 has an upper surface 26T on which a sixth chip pad 26A is disposed and a lower surface 26B opposite to the upper surface 26T. The sixth chip pad 26A is electrically connected to an integrated circuit inside the sixth semiconductor chip 26. The sixth chip pad 26A is disposed near one edge of the upper surface 26T of the sixth semiconductor chip 26 in the first direction FD, for example, a right edge as shown in FIG. 1. The sixth metal pillar 46 is disposed on the sixth chip pad 26A.

The sixth semiconductor chip 26 is stacked or disposed on the fifth semiconductor chip 25 by a fourth offset such that the fifth metal pillar layer 45 is not covered by the sixth semiconductor chip 26. The sixth semiconductor chip 26 is offset with respect to the fifth semiconductor chip 25 in the same direction as the fifth semiconductor chip 25 is offset with respect to the fourth semiconductor chip 24. The sixth semiconductor chip 26 is disposed between the third metal pillar 43 and the fifth metal pillar 45 and partially over the fifth semiconductor chip 25 in the vertical direction VD. The fifth metal pillar 45 extends substantially vertically near the side of the sixth semiconductor chip 26.

A sixth adhesive layer 36 is disposed on the lower surface 26B of the sixth semiconductor chip 26. The sixth adhesive layer 36 attaches the lower surface 26B of the sixth semiconductor chip 26 to the upper surface 25T of the fifth semiconductor chip 25.

Because the direction of offset of the fifth semiconductor chip 25 and the sixth semiconductor chip 26 is opposite to the direction of offset of the second semiconductor chip 22, the third semiconductor chip 23, and the fourth semiconductor chip 24, rather than the same direction of offset for all six semiconductor chips, a horizontal layout area occupied by the semiconductor chips 21 to 26 is smaller.

The metal pillars 41 to 46 may include copper (Cu). The metal pillars 41 to 46 may be copper pillars.

The bonding metal layers 51 to 54 may include gold (Au). The bonding metal layers 51 to 54 may be gold layers.

A first base metal layer 40Aa is disposed between the first chip pad 21A and the first metal pillar 41. A second base metal layer 40Ab is disposed between the second chip pad 22A and the second metal pillar 42. A third base metal layer 40Ac is disposed between the third chip pad 23A and the third metal pillar 43. A fourth base metal layer 40Ad is disposed between the fourth chip pad 24A and the fourth metal pillar 44. A fifth base metal layer 40Ae is disposed between the fifth chip pad 25A and the fifth metal pillar 45. A sixth base metal layer 40Af is disposed between the sixth chip pad 26A and the sixth metal pillar 46. Each of the first to sixth base metal layers 40Aa to 40Af suppresses metal included in a metal pillar from diffusing into a semiconductor chip. The first to sixth base metal layers 40Aa to 40Af may include titanium (Ti) or titanium tungsten (TiW). The first to sixth base metal layers 40Aa to 40Af may be a titanium layer.

A first barrier metal layer 40Ba is disposed between the first metal pillar 41 and the first bonding metal layer 51. A second barrier metal layer 40Bb is disposed between the second metal pillar 42 and the second bonding metal layer 52. A third barrier metal layer 40Bc is disposed between the third metal pillar 43 and the third bonding metal layer 53. A fourth barrier metal layer 40Bd is disposed between the fourth metal pillar 44 and the fourth bonding metal layer 54.

Each of the first to fourth barrier metal layers 40Ba to 40Bd suppresses metal included in a metal pillar from diffusing into the interface between a bonding metal layer and a bonding wire. In an embodiment, each of the first to fourth barrier metal layers 40Ba to 40Bd may include a nickel (Ni) layer. In an embodiment, the each of first to fourth barrier metal layer 40Ba to 40Bd may include a nickel (Ni) layer disposed on the surface of a bonding metal layer and a palladium (Pd) layer disposed on the surface of the nickel (Ni) layer.

An upper surface 51T of the first bonding metal layer 51 is be located higher than the upper surface 22T of the second semiconductor chip 22 in the vertical direction VD. The combined thickness of the second adhesive layer 32 and the second semiconductor chip 22 is F2 in the vertical direction VD. The combined thickness of the first base metal layer 40Aa under the first metal pillar 41, the first metal pillar 41, the first barrier metal layer 40Ba on the first metal pillar 41, and the first bonding metal layer 51 is H1 in the vertical direction VD. H1 is larger than F2. An upper surface 41T of the first metal pillar 41 is located higher than the upper surface 22T of the second semiconductor chip 22 in the example of FIG. 1.

An upper surface 52T of the second bonding metal layer 52 is located higher than the upper surface 23T of the third semiconductor chip 23 in the vertical direction VD. The combined thickness of the third adhesive layer 33 and the third semiconductor chip 23 is F3 in the vertical direction VD. The combined thickness of the second base metal layer 40Ab under the second metal pillar 42, the second metal pillar 42, the second barrier metal layer 40Bb on the second metal pillar 42, and the second bonding metal layer 52 is H2 in the vertical direction VD. H2 is larger than F3. An upper surface 42T of the second metal pillar 42 is located higher than the upper surface 23T of the third semiconductor chip 23 in the example of FIG. 1.

An upper surface 53T of the third bonding metal layer 53 is located higher than the upper surface 24T of the fourth semiconductor chip 24. The combined thickness of the fourth adhesive layer 34 and the fourth semiconductor chip 24 is F4 in the vertical direction VD. The combined thickness of the third base metal layer 40Ac under the third metal pillar 43, the third metal pillar 43, the third barrier metal layer 40Bc on the third metal pillar 43, and the third bonding metal layer 53 is H3 in the vertical direction VD. H3 is larger than F4. An upper surface 43T of the third metal pillar 43 is located higher than the upper surface 24T of the fourth semiconductor chip 24 in the example of FIG. 1.

An upper surface 54T of the fourth bonding metal layer 54 is located higher than the upper surface 25T of the fifth semiconductor chip 25. The combined thickness of the fifth adhesive layer 35 and the fifth semiconductor chip 25 is F5 in the vertical direction VD. The combined thickness of the fourth base metal layer 40Ad under the fourth metal pillar 44, the fourth metal pillar 44, the fourth barrier metal layer 40Bd on the fourth metal pillar 44, and the fourth bonding metal layer 54 is H4 in the vertical direction VD. H4 is larger than F5. An upper surface 44T of the fourth metal pillar 44 is located higher than the upper surface 25T of the fifth semiconductor chip 25 in the example of FIG. 1.

An upper surface 45T of the fifth metal pillar 45 is located higher than the upper surface 26T of the sixth semiconductor chip 26. The combined thickness of the sixth adhesive layer 36 and the thickness of the sixth semiconductor chip 26 is F6 in the vertical direction VD. The combined thickness of the fifth base metal layer 40Ae under the fifth metal pillar 45 and the fifth metal pillar 45 is H5 in the vertical direction VD. H5 is larger than F6.

Each of the heights H1, H2, H3, and H4 may have the same value. H5 is smaller than H1, H2, H3, and H4. The combined thickness of the sixth base metal layer 40Af under the sixth metal pillar 46 and the sixth metal pillar 46 is H6 in the vertical direction VD, and H6 is smaller than H5.

The first bonding wire 61, the second bonding wire 62, the third bonding wire 63, and the fourth bonding wire 64 are connected to the first bonding metal layer 51, the second bonding metal layer 52, the third bonding metal layer 53, and the fourth bonding metal layer 54, respectively.

The first bonding wire 61 extends substantially vertically with one end connected to the first bonding metal layer 51. The second bonding wire 62 extends substantially vertically with one end connected to the second bonding metal layer 52. The third bonding wire 63 extends substantially vertically with one end connected to the third bonding metal layer 53. The fourth bonding wire 64 extends substantially vertically with one end connected to the fourth bonding metal layer 54. The bonding wires 61 to 64 extend substantially vertically from or are erected substantially vertically on the surface of a corresponding bonding metal layer. The bonding wires 61 to 64 may include gold (Au).

The second sealing layer 70 is formed on the first sealing layer 10 to cover the semiconductor chips 21 to 26, the metal pillars 41 to 46, the bonding metal layers 51 to 54, and the bonding wires 61 to 64. By sealing the semiconductor chips 21 to 26, the metal pillars 41 to 46, the bonding metal layers 51 to 54, and the bonding wires 61 to 64, the second sealing layer 70 protects the semiconductor chips 21 to 26, the metal pillars 41 to 46, the bonding metal layers 51 to 54, and the bonding wires 61 to 64 from an external environment. The first sealing layer 10 is disposed under the first semiconductor chip 21 and the second sealing layer 70.

The second sealing layer 70 includes an insulating layer. The insulating layer may include an epoxy molding compound (EMC). The epoxy molding compound may include resin and various types of filler dispersed in the resin.

The upper ends of the bonding wires 61 to 64 and the upper ends of the metal pillars 45 and 46 are exposed along the upper surface of the second sealing layer 70.

The redistribution layer 80 is disposed on the second sealing layer 70, the bonding wires 61 to 64, the fifth metal pillar, and the sixth metal pillar 46.

The redistribution layer 80 includes redistribution line patterns 81 and a dielectric layer 82. The redistribution line patterns 81 are each connected to at least one of the bonding wires 61 to 64 and the metal pillars 45 and 46, and are connected to the semiconductor chips 21 to 26 through the bonding wires 61 to 64 and the metal pillars 41 to 46. The dielectric layer 82 insulates the redistribution line patterns 81 from each other.

Some of the redistribution line patterns 81 include under bump metallurgy (UBM) 81A. An external connection terminal 90 is connected to the UBM 81A. The UBM 81A is a wetting layer that facilitates adhesion of the external connection terminal 90 to the UBM 81A. The external connection terminal 90 may include a solder ball.

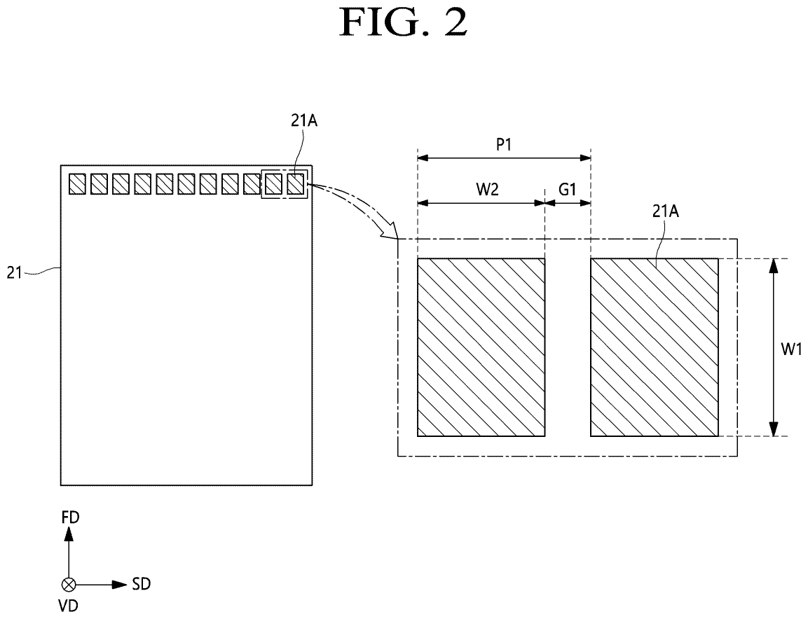

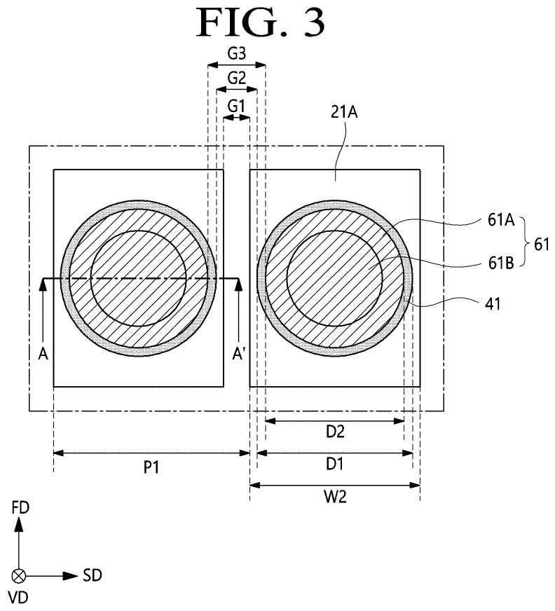

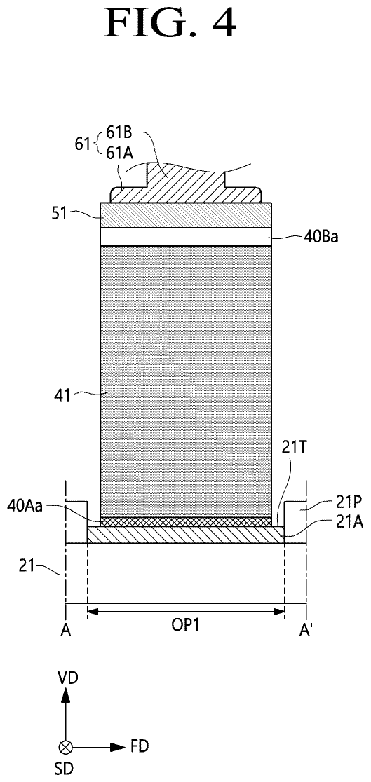

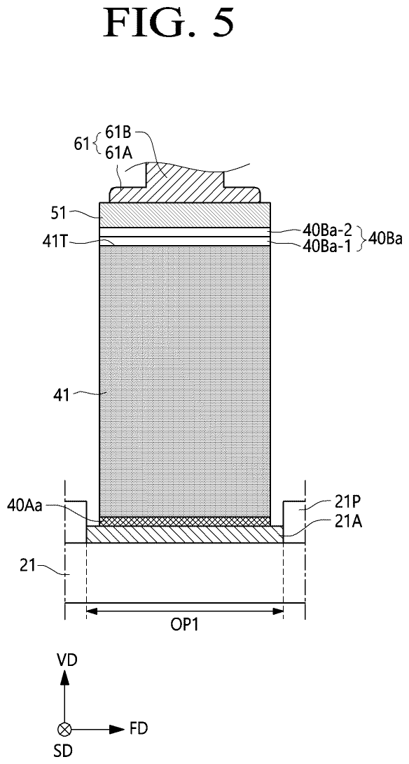

FIG. 2 is a plan view of a semiconductor chip, for example, as shown in FIG. 1. FIG. 3 is a plan view illustrating a chip pad, a metal pillar, and a bonding wire, for example, as shown in FIG. 1. FIG. 4 is a cross-sectional view taken along line A-A′ of FIG. 3. FIG. 5 is a cross-sectional view illustrating a chip pad, a metal pillar, and a bonding wire according to an embodiment of the present disclosure.

Referring to FIG. 2, a plurality of first chip pads 21A are disposed near one edge of the first semiconductor chip 21 in the first direction FD. Although the first chip pads 21A are disposed in line in a second direction SD in FIG. 2, the present disclosure is not limited to this example.

Each first chip pad 21A has a quadrangular shape. Each first chip pad 21A has a measurement W1 in the first direction FD, and a measurement W2 in the second direction SD. As illustrated in FIG. 2, W1 is different from W2. For example, W1 is larger than W2. In an embodiment, W1 is the same measurement as W2.

The plurality of first chip pads 21A is disposed with a pitch of P1 in the second direction SD. P1 is the combined measurement of the measurement W2 in the second direction SD of the first chip pad 21A and the distance or spacing G1 between neighboring first chip pads 21A.

The second semiconductor chip 22 and the third semiconductor chips 23 have the same shape as the first semiconductor chip 21. The fourth semiconductor chip 24, the fifth semiconductor chip 25, and the sixth semiconductor chip 26 may have a structure that is a mirror image to the structure of the first semiconductor chip 21 in the first direction FD because the chip pads are on opposite ends of the semiconductor chips.

Referring to FIG. 3, the first metal pillar 41 is disposed on the first chip pad 21A. The planar shape of the first metal pillar 41 may be circular. The present disclosure is not limited to this example, and the planar shape of the first metal pillar 41 may have other shapes such as quadrangular, hexagonal, polygonal, and oval shapes.

The first metal pillar 41 is narrower than the chip pad 21A. The measurement of the first metal pillar 41 in the second direction SD is D1. D1 is narrower than W2 of the first chip pad 21A in second direction SD.

The spacing between neighboring first metal pillars 41 is larger than the spacing between neighboring first chip pads 21A. The spacing or distance between neighboring first metal pillars 41 is G2, and G2 is larger than G1.

Referring to FIG. 3 and FIG. 4, the first bonding metal layer 51 is disposed on the first metal pillar 41, and the first bonding wire 61 is disposed on the first bonding metal layer 51. The first bonding wire 61 includes a bonding section 61A bonded to the first bonding metal layer 51 and a vertical section 61B connected to the bonding section 61A. The first bonding metal layer 51 is not shown in FIG. 3 to simplify the drawing.

The planar shape of the bonding section 61A of the first bonding wire 61 may be circular. The present disclosure is not limited to this example, and the planar shape of the bonding section 61A of the first bonding wire 61 may be another shape such as an oval shape.

The bonding section 61A of the first bonding wire 61 has a narrower measurement than the measurement of the first metal pillar 41 in the second direction SD. The measurement in the second direction SD of the bonding section 61A of the first bonding wire 61 is D2. D2 is narrower than D1 in the second direction SD of the first chip pad 21A. The spacing between the bonding sections 61A of neighboring first bonding wires 61 is G3. G3 is larger than G2.

Referring to FIG. 4, the first semiconductor chip 21 includes the first chip pad 21A and a first passivation layer 21P having a first opening OP1 through which the first chip pad 21A is exposed. The first chip pad 21A may include aluminum (Al). The first passivation layer 21P may include polyimide isoindro quindzoline (PIQ).

The first metal pillar 41 is disposed on the first chip pad 21A exposed through the first opening OP1 formed in the first passivation layer 21P.

The planar area of the first opening OP1 is larger than the planar area of the first metal pillar 41. The edge of the first metal pillar 41 is spaced apart from the first passivation layer 21P. The first passivation layer 21P may contact the first metal pillar 41 in an embodiment.

The first base metal layer 40Aa is disposed between the first metal pillar 41 and the first chip pad 21A. The first base metal layer 40Aa is disposed on the surface 21T of the first chip pad 21A. The first base metal layer 40Aa contacts the first chip pad 21A and electrically connects the first chip pad 21A and the first metal pillar 41. The first base metal layer 40Aa may include titanium (Ti) or titanium tungsten (TiW). The base metal layer 40A may be a titanium layer. The description of the first base metal layer 40Aa similarly applies to the second to sixth base metal layers 40Ab to 40Af of FIG. 1.

The first metal pillar 41 is disposed on the base metal layer 40Aa. The first metal pillar 41 may include copper (Cu).

The first barrier metal layer 40Ba is disposed on the first metal pillar 41. The first barrier metal layer 40Ba may include nickel (Ni). The first barrier metal layer 40Ba may be a nickel layer. The description of the first barrier metal layer 40Ba similarly applies to the second to fourth barrier metal layer 40Bb to 40Bd of FIG. 1.

Referring to FIG. 5, the first barrier metal layer 40Ba may include a first layer 40Ba-1 and a second layer 40Ba-2. The first layer 40Ba-1 is disposed on the upper surface 41T of the first metal pillar 41, and the second layer 40Ba-2 is disposed on the first layer 40Ba-1. The first layer 40Ba-1 may include nickel (Ni). The first layer 40Ba-1 may be a nickel layer. The second layer 40Ba-2 may include palladium (Pd). The second layer 40Ba-2 may be a palladium layer.

The metal included in the first metal pillar 41 may diffuse into the interface between the first bonding metal layer 51 and the first bonding wire 61. This diffusion generates an intermetallic compound that reduces the bonding force between the first bonding metal layer 51 and the first bonding wire 61. The first barrier metal layer 40Ba suppresses diffusion of the metal included in the first metal pillar 41 into the interface between the first bonding metal layer 51 and the first bonding wire 61. The description of the first barrier metal layer 40Ba similarly applies to the second to fourth barrier metal layer 40Bb to 40Bd.

The first bonding metal layer 51 is disposed on the first barrier metal layer 40Ba. The first bonding metal layer 51 may include gold (Au).

The first bonding wire 61 is bonded onto the first bonding metal layer 51. The first bonding wire 61 may include gold (Au). The bonding section 61A of the first bonding wire 61 is bonded to the first bonding metal layer 51. The vertical section 61B of the first bonding wire 61 extends substantially vertically from the bonding section 61A.

Each of the metal pillars 42 to 44 of FIG. 1 has substantially the same structure as the structure of the first metal pillar 41. Each of the bonding wires 62 to 64 of FIG. 1 has substantially the same structure as the first bonding wire 61 except that the length of the vertical section 61B is different, as shown in FIG. 1. Among the bonding wires 61 to 64, the length of the vertical section 61B of the first bonding wire 61 is longest among the vertical sections, the length of the vertical section of the second bonding wire 62 is the second longest among the vertical sections, the length of the vertical section of the third bonding wire 63 is the third longest among the vertical sections, and the length of the vertical section of the fourth bonding wire 64 is shortest among the vertical sections.

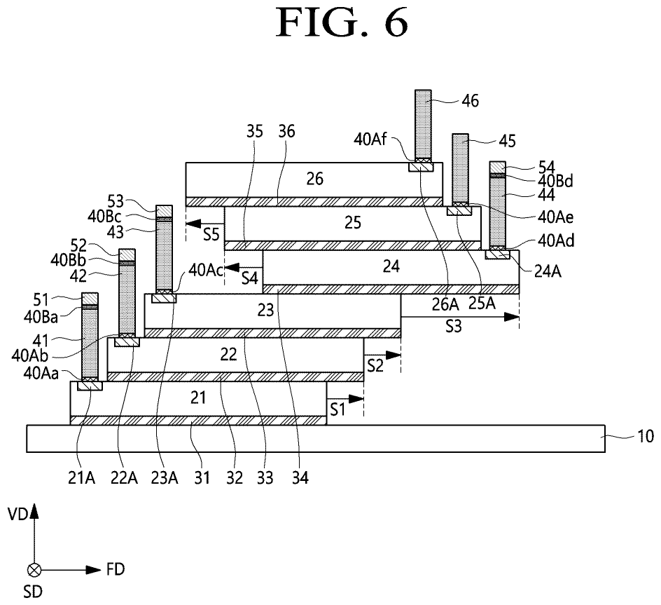

FIG. 6 to FIG. 8 are cross-sectional views illustrating a fan-out semiconductor package formed using a method for manufacturing a fan-out semiconductor package according to an embodiment of the present disclosure.

Referring to FIG. 6, a first semiconductor chip 21 formed with a first metal pillar 41 and a first bonding metal layer 51 is disposed on a first sealing layer 10, a second semiconductor chip 22 formed with a second metal pillar 42 and a second bonding metal layer 52 is stacked on the first semiconductor chip 21, a third semiconductor chip 23 formed with a third metal pillar 43 and a third bonding metal layer 53 is stacked on the second semiconductor chip 22, a fourth semiconductor chip 24 formed with a fourth metal pillar 44 and a fourth bonding metal layer 54 is stacked on the third semiconductor chip 23, a fifth semiconductor chip 25 formed with a fifth metal pillar 45 is stacked on the fourth semiconductor chip 24, and a sixth semiconductor chip 26 formed with a sixth metal pillar 46 is stacked on the fifth semiconductor chip 25.

A metal pillar may be formed by forming a seed layer on a semiconductor chip, forming, on the seed layer, a plating resist pattern that has an opening that is a template for the metal pillar, growing a metal bump in the opening of the plating resist pattern, removing the plating resist pattern by a strip process, and removing, by an etching process, the seed layer not formed over the metal bump.

The seed layer may be formed by a deposition method such as sputtering. The metal bump may be grown on the seed layer using a plating process. The seed layer and the metal bump may include copper (Cu). The metal pillar includes the seed layer and the metal bump grown on the seed layer. The metal pillar is formed with a height larger than the thickness of the semiconductor chip in the vertical direction VD.

A bonding metal layer may be grown on the metal bump by a plating process after forming the metal bump and before removing the plating resist pattern.

In an embodiment, each of first to sixth base metal layers 40Aa to 40Af may be formed by forming a pre-base metal layer before forming the seed layer on the semiconductor chip and, after removing the seed layer not formed below the metal bump, and etching the pre-base metal layer exposed due to removal of the seed layer. The pre-base metal layer may be formed by a deposition method such as sputtering. The first to sixth base metal layers 40Aa to 40Af may include titanium (Ti) or titanium tungsten (TiW). Each of the first to sixth base metal layers 40Aa to 40Af may be a titanium layer.

In an embodiment, each of first to fourth barrier metal layer 40Ba to 40Bd may be formed on the metal bump before forming the bonding metal layer after forming the metal bump. Each of the first to fourth barrier metal layers 40Ba to 40Bd may be grown on the metal bump utilizing a plating process. Each of the first to fourth barrier metal layers 40Ba to 40Bd may be a nickel (Ni) layer or a structure in which a nickel (Ni) layer and a palladium (Pd) layer are stacked.

The first to fourth bonding metal layers 51 to 54 may be grown on the first to fourth barrier metal layer 40Ba to 40Bd utilizing a plating process. The first to fourth bonding metal layers 51 to 54 may include Gold (au).

The first sealing layer 10 may be attached to a carrier substrate (not illustrated). A process of manufacturing a fan-out semiconductor package according to an embodiment may be performed on the carrier substrate.

The first sealing layer 10 may be a member formed as a sealing material is processed in the form of a film. The first sealing layer 10 may include an epoxy molding compound film (EMC film).

The first semiconductor chip 21 is attached to the first sealing layer 10 using the first adhesive layer 31.

The second semiconductor chip 22 is stacked on the first semiconductor chip 21 and is offset with respect to the first chip 21 in the first direction FD. The second semiconductor chip 22 is offset by a first distance S1 with respect to the first semiconductor chip 21. The second semiconductor chip 22 is disposed beside or spaced apart from the first metal pillar 41 in the first direction FD and partially over the first semiconductor chip 21 in the vertical direction VD. The spacing between the second metal pillar 42 and the first metal pillar 41 is wider than the spacing between the second semiconductor chip 22 and the first metal pillar 41. The second semiconductor chip 22 is attached to the first semiconductor chip 21 using the second adhesive layer 32.

The third semiconductor chip 23 is stacked on the second semiconductor chip 22. The third semiconductor chip 23 is offset with respect to the second semiconductor chip 22 in substantially the same direction as the second semiconductor chip 22 is offset with respect to the first semiconductor chip 21. The third semiconductor chip 23 is offset by a second distance S2 with respect to the second semiconductor chip 22. The second distance S2 may be substantially the same distance as the first distance S1. The third semiconductor chip 23 is disposed beside or spaced apart from the second metal pillar 42 in the first direction FD and partially over the second semiconductor chip 22 in the vertical direction VD. The spacing between the third metal pillar 43 and the second metal pillar 42 is wider than the spacing between the third semiconductor chip 23 and the second metal pillar 42. The third semiconductor chip 23 is attached to the second semiconductor chip 22 using the third adhesive layer 33.

The fourth semiconductor chip 24 is stacked on the third semiconductor chip 23. The fourth semiconductor chip 24 is offset with respect to the third semiconductor chip 23 in substantially the same direction as the third semiconductor chip 23 is offset with respect to the second semiconductor chip 22. The fourth semiconductor chip 24 is offset by a third distance S3 with respect to the third semiconductor chip 23. The third distance S3 may be larger than the first distance S1. The third distance S3 may be two times the first distance S1. The fourth semiconductor chip 24 is disposed beside or spaced apart from the third metal pillar 43 in the first direction FD and partially over the third semiconductor chip 23 in the vertical direction VD. The spacing between the fourth metal pillar 44 and the third metal pillar 43 is wider than the spacing between the fourth semiconductor chip 24 and the third metal pillar 43. The fourth semiconductor chip 24 is attached to the third semiconductor chip 23 using the fourth adhesive layer 34.

The fifth semiconductor chip 25 is stacked on the fourth semiconductor chip 24. The fifth semiconductor chip 25 is offset with respect to the fourth semiconductor chip 24 in a direction opposite to the direction that the fourth semiconductor chip 24 is offset with respect to the third semiconductor chip 23. The fifth semiconductor chip 25 is offset by a fourth distance S4 with respect to the fourth semiconductor chip 24. The fourth distance S4 may be smaller than the third distance S3. For example, the fourth distance S4 may be substantially the same as the first distance S1. The fifth semiconductor chip 25 is disposed between the third metal pillar 43 and the fourth metal pillar 44 and partially over the fourth semiconductor chip 24 in the vertical direction VD. The spacing between the fifth metal pillar 45 and the fourth metal pillar 44 is wider than the spacing between the fifth semiconductor chip 25 and the fourth metal pillar 44. The fifth semiconductor chip 25 is attached to the fourth semiconductor chip 24 using the fifth adhesive layer 35.

The sixth semiconductor chip 26 is stacked the fifth semiconductor chip 25. The sixth semiconductor chip 26 is offset with respect to the fifth semiconductor chip 25 in the same direction as the fifth semiconductor chip 25 is offset with respect to the fourth semiconductor chip 24. The sixth semiconductor chip 26 is offset by a fifth distance S5 with respect to the fifth semiconductor chip 25. The fifth distance S5 may be substantially the same distance as the fourth distance S4. The sixth semiconductor chip 26 is disposed beside or spaced apart from the fifth metal pillar 45 in the first direction FD and partially over the fifth semiconductor chip 25 in the vertical direction VD. The spacing between the sixth metal pillar 46 and the fifth metal pillar 45 is wider than the spacing between the sixth semiconductor chip 26 and the fifth metal pillar 45. The sixth semiconductor chip 26 is attached to the fifth semiconductor chip 25 using the sixth adhesive layer 36.

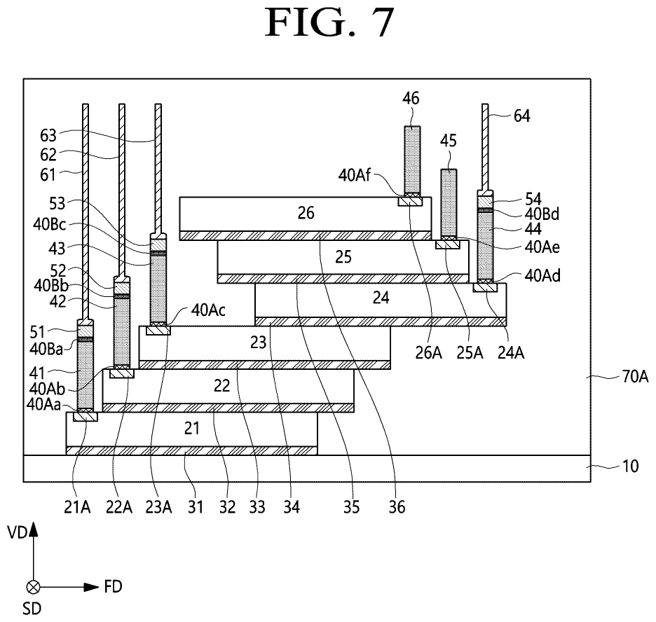

Referring to FIG. 7, bonding wires 61 to 64 and a pre-sealing layer 70A are formed.

The bonding wires 61 to 64 are connected to the bonding metal layers 51 to 54, respectively. The bonding wires 61 to 64 may be formed including a conductive material. The conductive material may include gold (Au).

The bonding wires 61 to 64 are formed by a wire bonding process utilizing a wire bonding device (not illustrated) including a capillary. The capillary of the wire bonding device form a bonding ball at a first end of a metal wire, bonding the formed bonding ball to a bonding metal layer, pulling a second end of the metal wire in a vertical direction away from the bonding metal layer, for example, in an upward direction, and cutting the second end of the metal wire when the second end of the metal wire is extended to a desired length, thereby forming a bonding wire.

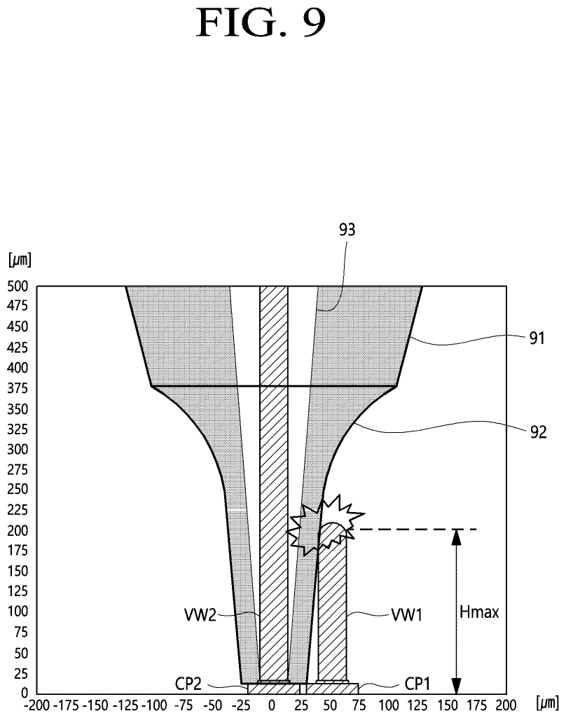

FIG. 9 is a diagram of a capillary of a wire bonding device. Referring to FIG. 9, a capillary of a wire bonding device includes a body 91 and a tip 92 disposed at the distal or lower end of the body 91. A through hole 93 passes through the body 91 and the tip 92 in an axial direction. During wire bonding, a metal wire VW2 passes through the through hole 93 and is discharged through the exit of the through hole 93 at the distal or lower end of the tip 92. The tip 92 of the capillary has a shape that is tapered inward toward the distal or lower end of the tip 92.

After forming a first bonding wire VW1 on a first chip pad CP1, the capillary is lowered toward a second chip pad CP2 near the first chip pad to form a bonding wire VW2 on the second chip pad CP2. When the pitch of the chip pad is small, the tip 92 of the capillary collides with the first bonding wire VW1. As a result, the maximum height Hmax or length of a bonding wire that can be formed is limited to avoid capillary collisions that may damage other bonding wires.

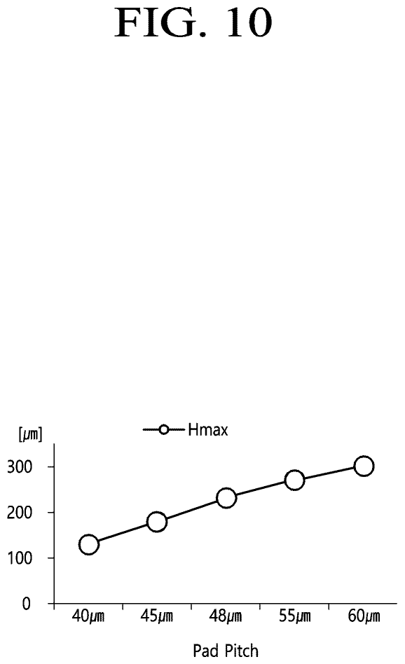

FIG. 10 is a graph showing change in the maximum height of a bonding wire versus change in the pitch of a chip pad. Referring to FIG. 10, a maximum height Hmax of a bonding wire is proportional to the pitch of a chip pad. When the pitch of a chip pad decreases, the maximum height Hmax of a bonding wire decreases.

As the maximum height of a bonding wire decreases, the quantity of semiconductor chips that can be stacked may be limited. When bonding a bonding wire to a lower semiconductor chip, a capillary may collide with an upper semiconductor chip, making forming the bonding wire difficult.

In an embodiment of the present disclosure, because a metal pillar is disposed between a semiconductor chip and a bonding wire, a greater quantity of semiconductor chips may be stacked without restriction by the maximum height of the bonding wire than the quantity of semiconductor chips that may be stacked without use of metal pillars.

Because the upper surface of a metal pillar disposed on a first semiconductor chip is disposed higher than the upper surface of a second semiconductor chip disposed above the first semiconductor chip in the vertical direction VD, and because the spacing between the metal pillar on the first semiconductor chip and a metal pillar on the second semiconductor chip is wider than the spacing between the metal pillar on the first semiconductor chip and the second semiconductor chip, a capillary may be prevented from colliding with the second semiconductor chip and the metal pillar on the second semiconductor chip when bonding a bonding wire to the metal pillar on the first semiconductor chip.

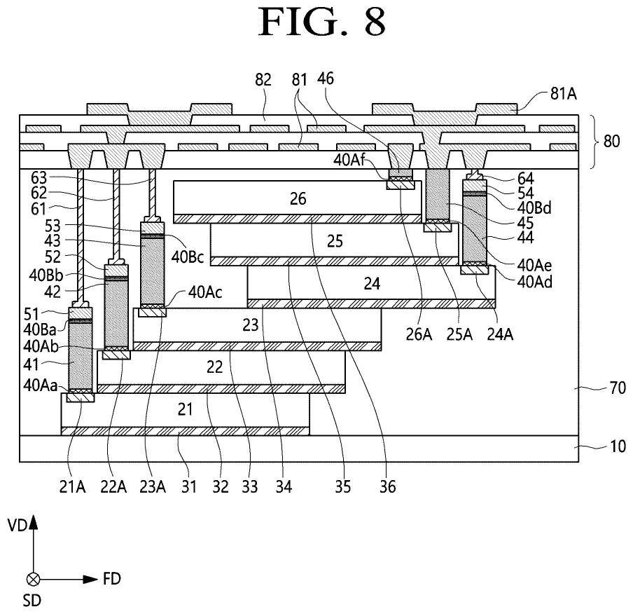

Referring to FIG. 7, the pre-sealing layer 70A is formed to cover and seal the semiconductor chips 21 to 26, the metal pillars 41 to 46, the bonding metal layers 51 to 54, and the bonding wires 61 to 64. The pre-sealing layer 70A is a preliminary structure utilized to form a second sealing layer 70, such as shown in FIG. 8,) and is formed at a height taller than the higher of the second sealing layer 70 in the vertical direction VD.

The pre-sealing layer 70A may be formed by a molding process using a liquid sealant. The molding process may include placing in a mold (not illustrated) the first sealing layer 10 on which the semiconductor chips 21 to 26, the metal pillars 41 to 46, the bonding metal layers 51 to 54, and the bonding wires 61 to 64 are disposed, introducing a liquid sealant into the mold, and curing the liquid sealant. The sealant may include an epoxy mold compound (EMC).

Referring to FIG. 8, the second sealing layer 70 is formed by thinning the pre-sealing layer 70A. A redistribution layer 80 is formed.

The thinning process may include a chemical mechanical polishing (CMP) or grinding process. During the thinning process, the bonding wires 61 to 64 and the metal pillars 45 and 46 are exposed along the upper surface of the second sealing layer 70.

The redistribution layer 80 includes redistribution line patterns 81 and a dielectric layer 82 that insulates the redistribution line patterns 81. Some of the redistribution line patterns 81 are connected to the bonding wires 61 to 64 and the metal pillars 45 and 46. Some of the redistribution line patterns 81 include ball lands 81A. The ball lands 81A are disposed on the dielectric layer 82.

External connection terminals 90 of FIG. 1 are attached to the ball lands 81A. The external connection terminals 90 may include solder balls.

Although the detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

1. A fan-out semiconductor package comprising:
a semiconductor chip;
a metal pillar disposed on the semiconductor chip;
a bonding metal layer disposed on the metal pillar;
a bonding wire disposed on the bonding metal layer;
a first sealing layer over the semiconductor chip, and surrounding the metal pillar, the bonding metal layer, and the bonding wire; and
a redistribution layer disposed on the first sealing layer and the bonding wire.

2. The fan-out semiconductor package according to claim 1, wherein the metal pillar includes copper, and the bonding metal layer includes gold.

3. The fan-out semiconductor package according to claim 1, further comprising a barrier metal layer disposed between the metal pillar and the bonding metal layer.

4. The fan-out semiconductor package according to claim 3, wherein the barrier metal layer comprises a nickel layer.

5. The fan-out semiconductor package according to claim 3, wherein the barrier metal layer comprises:
a nickel layer on the metal pillar; and
a palladium layer between the nickel layer and the bonding metal layer.

6. The fan-out semiconductor package according to claim 1, further comprising a base metal layer between the semiconductor chip and the metal pillar.

7. The fan-out semiconductor package according to claim 6, wherein the base metal layer includes titanium (Ti).

8. The fan-out semiconductor package according to claim 1,
wherein the bonding wire comprises a bonding section coupled to the bonding metal layer, and
wherein the length of the metal pillar is longer than the length of the bonding section.

9. The fan-out semiconductor package according to claim 1,
wherein the metal pillar is disposed on a chip pad of the semiconductor chip, and
wherein a dimension of the metal pillar is narrower than a dimension of the chip pad in a first direction.

10. The fan-out semiconductor package according to claim 1, further comprising a second sealing layer on which the semiconductor chip and the first sealing layer are disposed.

11. A fan-out semiconductor package comprising:
a first semiconductor chip;
a first metal pillar disposed on the first semiconductor chip;
a bonding metal layer disposed on the first metal pillar;
a second semiconductor chip stacked on the first semiconductor chip and offset from the first semiconductor chip by a first distance in a first direction;
a second metal pillar disposed on the second semiconductor chip;
a bonding wire disposed on the bonding metal layer;
a sealing layer over the first semiconductor chip and the second semiconductor chip, and surrounding the first metal pillar, the second metal pillar, the bonding metal layer, and the bonding wire; and
a redistribution layer disposed on the sealing layer, the bonding wire, and the second metal pillar.

12. The fan-out semiconductor package according to claim 11, wherein a first surface of the bonding metal layer is located farther away from the first semiconductor chip in a second direction than a first surface of the second semiconductor chip, wherein the first surface of the second semiconductor chip is a surface of the second semiconductor chip located farthest away from the first semiconductor chip.

13. The fan-out semiconductor package according to claim 11, wherein a first surface of the first metal pillar is located farther away from the first semiconductor chip in a second direction than a first surface of the second semiconductor chip, wherein the first surface of the second semiconductor chip is a surface of the second semiconductor chip located farthest away from the first semiconductor chip.

14. The fan-out semiconductor package according to claim 11, wherein the spacing between the first metal pillar and the second metal pillar in the first direction is larger than the spacing between the first metal pillar and the second semiconductor chip in the first direction.

15. The fan-out semiconductor package according to claim 11, wherein the first metal pillar and the second metal pillar include copper, and the bonding metal layer includes gold.

16. The fan-out semiconductor package according to claim 11, further comprising a barrier metal layer between the first metal pillar and the bonding metal layer.

17. The fan-out semiconductor package according to claim 16, wherein the barrier metal layer comprises one of a nickel layer and a stack structure comprising a nickel layer and a palladium layer.

18. A semiconductor package comprising:
a metal pillar disposed on a semiconductor chip;
a bonding wire disposed between the metal pillar and a redistribution layer; and
a sealing layer over the semiconductor chip and surrounding the metal pillar and the wire, wherein the redistribution layer is disposed on the first sealing layer and the wire.

19. The fan-out semiconductor package according to claim 18,
wherein the bonding wire comprises a bonding section coupled to the bonding metal layer; and
wherein a length of the metal pillar is longer than a length of the bonding section.

20. The fan-out semiconductor package according to claim 18,
wherein the metal pillar is disposed on a chip pad of the semiconductor chip, and
wherein a measurement of the metal pillar is narrower than a measurement of the chip pad in a first direction.
